(19) United States
(12) Patent Application Publication
(10) Pub. No.: US 2015/0163959 A1
(43) Pub. Date: Jun. 11, 2015

(54) ELECTRONIC DEVICE WITH FAN MODULE

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: BO YANG, Wuhan (CN); ZHI-PING WU, Wuhan (CN)

(21) Appl. No.: 14/517,576

(22) Filed: Oct. 17, 2014

(30) Foreign Application Priority Data
Dec. 6, 2013 (CN) 201310650414.4

(51) Int. Cl. H05K 7/20

(52) U.S. Cl. CPC H05K 7/20145

(57) ABSTRACT

An electronic device includes an enclosure defining a plurality of air inlets and including a bottom plate, a covering plate secured to the enclosure and defining a first air outlet, a first heating component mounted on the bottom plate, a first fan module located on the first heating component, and an air duct located between the covering plate and the first fan module. An air path is defined by the air inlets, the first heating component, the first fan module, the air duct, and the first air outlet under the action of the first fan module, and air flows in the air path to cool the first heating component.

### FIELD

The subject matter herein generally relates to an electronic device with fan modules.

### BACKGROUND

An electronic device, such as a computer, generally includes an enclosure, a central processing unit (CPU) with a fan module, memories, and a plurality of expansion cards, such as graphics cards, located in the enclosure. The fan module is operated to guide air to flow to the CPU to cool the CPU, and then the hot air from the CPU is flowed out of the enclosure under an action of a system fan module.

### BRIEF DESCRIPTION OF THE DRAWINGS

Implementations of the present technology will now be described, by way of example only, with reference to the attached figures.

FIG. 1 is an exploded, isometric view of an embodiment of an electronic device.

FIG. 2 is an assembled, isometric view of the electronic device of FIG. 1, without a covering plate.

FIG. 3 is similar to FIG. 2, but viewed from a different angle.

FIG. 4 is an assembled, isometric view of the electronic device of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

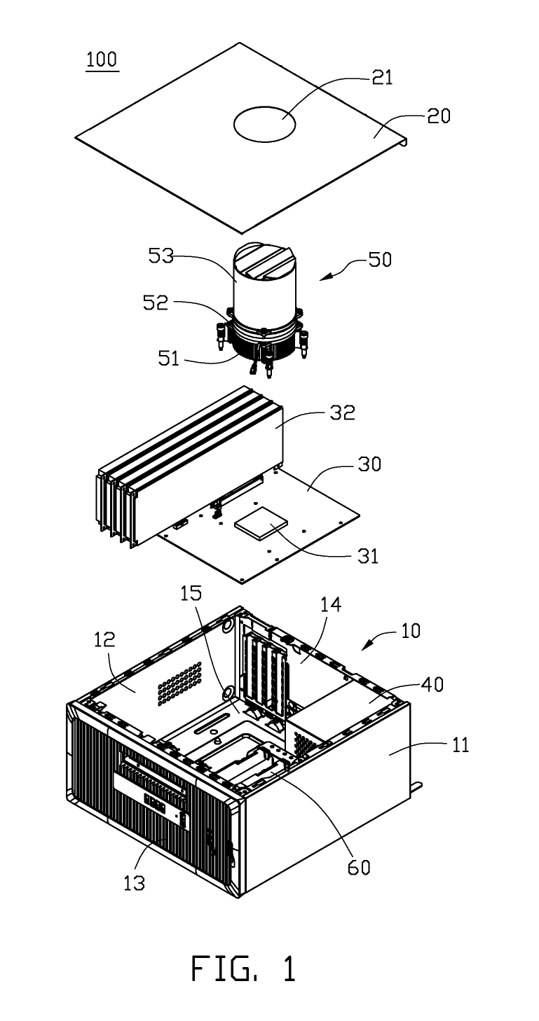

FIG. 1 illustrates an electronic device in accordance with an embodiment. The electronic device includes an enclosure 100, a main board 30, a power supply 40, a first fan module 44, and a second fan module 50 located in the enclosure 100.

The enclosure 100 can include a case 10 and a covering plate 20. The case 10 includes a first side plate 11, a second side plate 12, a front plate 13, a rear plate 14, and a bottom plate 15.

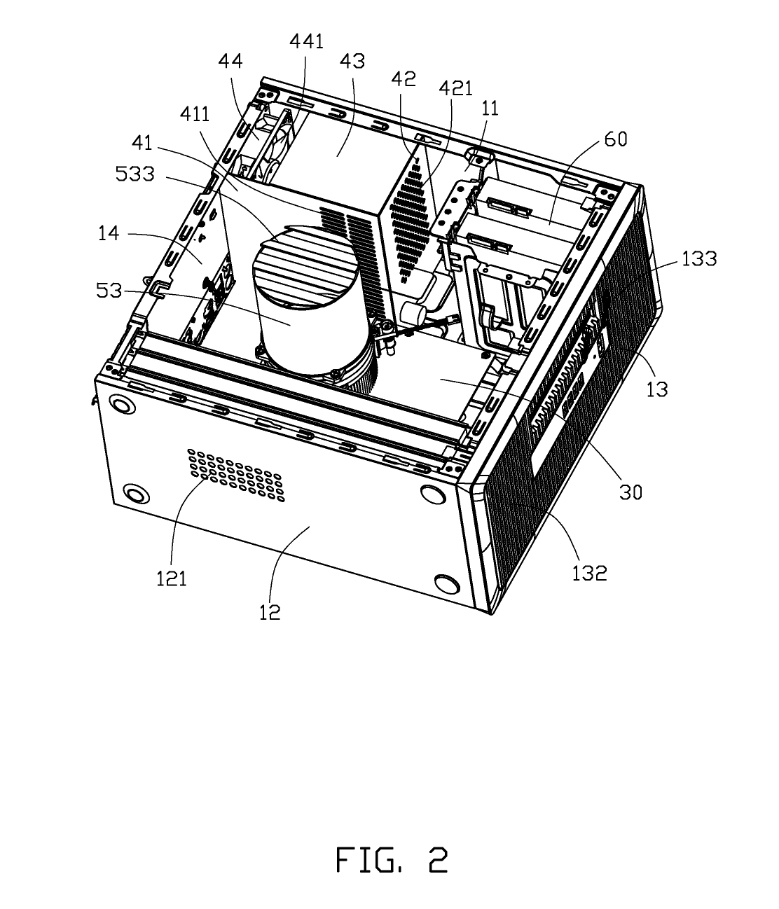

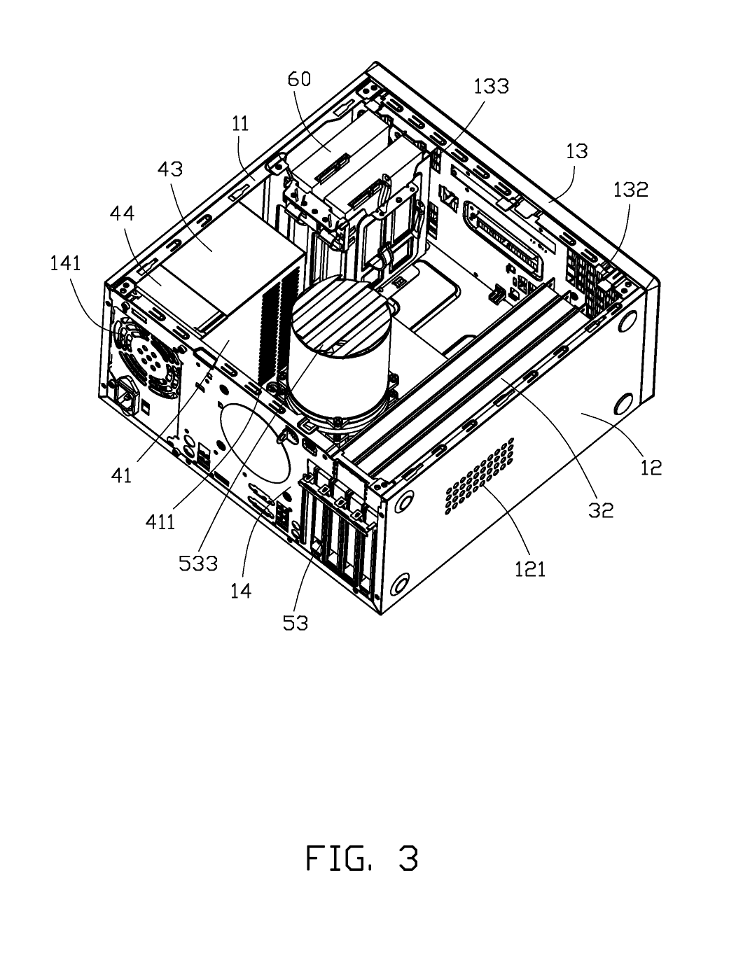

FIGS. 2 and 3 illustrate that the main board 30 is mounted on the bottom plate 15 and adjacent to the second side plate 12 and the rear plate 14. The main board 30 has a first heating component 31 and a second heating component 32. The second side plate 12 defines a plurality of first air inlets 121. In at least one embodiment, the first heating component 31 is a CPU, and the second heating component 32 is one or more graphics cards.

The power supply 40 is mounted on the bottom plate 15, adjacent to the rear plate 14, and abuts against the first side plate 11. The power supply 40 includes a first wall 41 substantially parallel to the first side plate 11, a second wall 42 substantially parallel to the rear plate 41, and a third wall 43 substantially parallel to the bottom plate 15. The first wall 41 defines a plurality of first ventilation holes 411. The second wall 42 defines a plurality of second ventilation holes 421. The first fan module 44 includes a first fan 441 secured to the rear plate 14. The rear plate 14 further defines a plurality of first air outlets 141 corresponding to the first fan 441.

The second fan module 50 is mounted on the first heating component 31 and includes a heat sink 51, a second fan 52, and an air duct 53. The second fan 52 is operable to guide air to flow from the first heating component 31 to the air duct 53. The air duct 53 has a cover 533. In at least one embodiment, the air duct 53 is hollow cylindrical to surround the second fan 52. When the second fan 52 is operated, the cover 533 can be opened by the air flow. When the second fan 52 is stopped operating, the cover 533 covers the air duct 53, inhibiting dust from flowing into the enclosure 100. The covering plate 20 defines a second air outlet 21 aligned with the cover 533. A height of the air duct 53 is substantially equal to a distance between the covering plate 20 and the second fan 52.

A third heating component 60 is secured to the front plate 13 and adjacent to the first side plate 11. In one embodiment, the third heating component 60 is a hard disk drive module. The front plate 13 further defines a second air inlet 132 and a third air inlet 133. The second air inlet 132 is adjacent to the second side plate 12. The third air inlet 133 is adjacent to the first side plate 11 and faces to the third heating component 60. Each of the second air inlet 132 and the third air inlet 133 is a shuttered inlet.

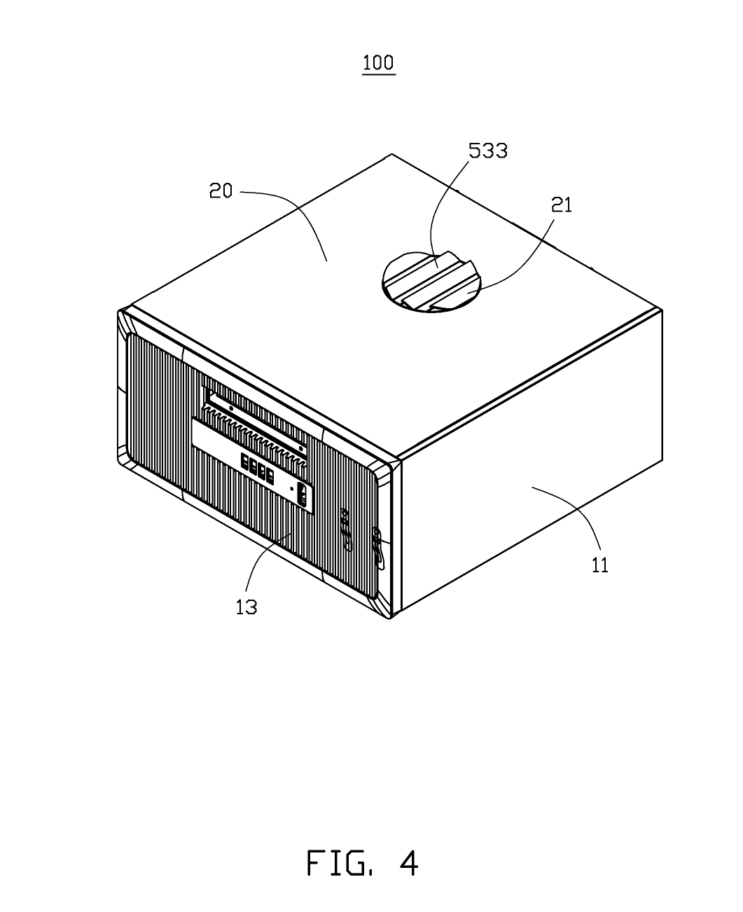

Referring to FIGS. 1-4, when the electronic device 100 is operated, the first fan 441 and the second fan 52 guide air to flow into the enclosure 10 from the first air inlets 121, the second air inlets 132, and the third air inlets 133. A first air path is defined by the third heating component 60, the first ventilation hole 411, the second ventilation hole 421, the power supply 40, the first fan 441, and the first air outlets 141 under the action of the first fan 441, so that the third heating component 60 and the power supply 40 are cooled. A second air path is defined by the first heating component 31, the second heating component 32, the second fan 52, the air duct 53, and the second air outlet 21 under the action of the second fan 52, so that the first heating component 31 and the second heating component 32 are cooled.

The embodiments shown and described above are only examples. Many details are often found in the art such as the other features of an electronic device. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims. It will therefore be appreciated that the embodiments described above may be modified within the scope of the claims.

What is claimed is:

1. An electronic device comprising:
an enclosure defining a plurality of air inlets and comprising a bottom plate;
a covering plate secured to the enclosure and defines a first air outlet;
a first heating component mounted on the bottom plate;
a first fan module located on the first heating component; and
an air duct located between the covering plate and the first fan module;
wherein an air path is defined by the air inlets, the first heating component, the first fan module, the air duct, and the first air outlet under the action of the first fan module.

2. The electronic device of claim 1, further comprising a second heating component, wherein the first fan module is operable to guide air to flow from the air inlets to the first air outlet via the second heating component, the first fan module, and the air duct.

3. The electronic device of claim 1, wherein the air duct has a shuttered cover, when the first fan module is operated, the shuttered cover is opened by the air flowing from the first fan module, allowing the air to flow to the air outlet.

4. The electronic device of claim 3, wherein the air duct is hollow cylindrical.

5. The electronic device of claim 1, wherein the enclosure further comprises a first side plate, a second side plate, a front plate, and a rear plate, the first side plate is substantially parallel to the second side plate, the front plate is substantially parallel to the rear plate and perpendicular to the first side plate, the second side plate defines a plurality of first air inlets facing to the second heating component, and the front plate defines a plurality of second air inlets adjacent to the second side plate.

6. The electronic device of claim 5, further comprising a power supply secured to the rear plate and a second fan module located between the rear plate and the power supply, wherein the rear plate defines a second air outlet facing to the second fan module, and another air path is defined by the air inlets, the power supply, the second fan module, and the second air outlet under the action of the second fan module.

7. The electronic device of claim 6, wherein the power supply comprises a first wall and a second wall, the first wall defines a plurality of first ventilation holes, and the second wall defines a plurality of second ventilation holes, and the air flows into the power supply via the first ventilation holes and the second ventilation holes.

8. The electronic device of claim 7, wherein the first wall is substantially parallel to the second side plate, and the second wall is substantially parallel to the rear plate.

9. The electronic device of claim 7, further comprising a third heating component located between the second wall and the front plate, wherein the front plate further defines a plurality of third air inlets facing to the third heating component and adjacent to the first side plate.

10. The electronic device of claim 1, wherein a height of the air duct is substantially equal to a distance between the covering plate and the first fan module.

11. An electronic device comprising:
an enclosure defining a plurality of air inlets and comprising a bottom plate;
a covering plate secured to the enclosure and defines a first air outlet;
a main board mounted on the bottom plate;
a first heating component secured to the main board;
a second heating component secured to the main board adjacent to the first heating component;
a first fan module located on the first heating component; and
an air duct located between the covering plate and the first fan module;
wherein the first fan module is operable to guide air to flow from the air inlets and out of the first air outlet via the first heating component, the second heating component, the first fan module, and the air duct to cool the first heating component and the second heating component.

12. The electronic device of claim 11, wherein the air duct has a shuttered cover, when the first fan module is operated, the shuttered cover is opened by the air flowing from the first fan module, allowing the air to flow to the air outlet.

13. The electronic device of claim 11, wherein the enclosure further comprises a first side plate, a second side plate, a front plate, and a rear plate, the first side plate is substantially parallel to the second side plate, the front plate is substantially parallel to the rear plate and perpendicular to the first side plate, the second side plate defines a plurality of first air inlets facing to the second heating component.

14. The electronic device of claim 13, the front plate defines a plurality of second air inlets adjacent to the second side plate.

15. The electronic device of claim 13, further comprising a power supply secured to the rear plate and a second fan module located between the rear plate and the power supply, wherein the rear plate defines a second air outlet facing to the second fan module, and another air path is defined by the air inlets, the power supply, the second fan module, and the second air outlet under the action of the second fan module.

16. The electronic device of claim 15, wherein the power supply comprises a first wall and a second wall, the first wall defines a plurality of first ventilation holes, and the second wall defines a plurality of second ventilation holes, and the air flows into the power supply via the first ventilation holes and the second ventilation holes.

17. The electronic device of claim 16, wherein the first wall is substantially parallel to the second side plate, and the second wall is substantially parallel to the rear plate.

18. The electronic device of claim 16, further comprising a third heating component located between the second wall and the front plate, wherein the front plate further defines a plurality of third air inlets facing to the third heating component and adjacent to the first side plate.

19. The electronic device of claim 11, wherein a height of the air duct is substantially equal to a distance between the covering plate and the first fan module.

20. An electronic device comprising:
an enclosure defining having:
a first side plate;
a second side plate opposite, and substantially parallel, to the first side plate;
a front plate;
a rear plate opposite, and substantially parallel, to the front plate;
a bottom plate; and
a covering plate opposite, and substantially parallel, to the bottom plate;
wherein, the first side plate and the second side plate are substantially perpendicular to the front plate and the rear plate and the bottom plate and the covering plate are substantially perpendicular to the first side plate, the second side plate, the rear plate and the front plate;
an electronic component mounted on the bottom plate;
a first fan module positioned between the electronic component and the covering plate; and
an air duct;
wherein, a plurality of air inlets are defined in at least one of the first side plate, the second side plate, the rear plate, the front plate and the bottom plate;
wherein, a first air outlet is defined in the covering plate;
wherein, the air duct is positioned substantially between the first fan module and the first air outlet; and
wherein, when in operation, the fan module creates a path of air entering from at least a portion of the plurality of air inlets, to the first electronic component, flowing over the air duct, through the first fan module and the air duct and exiting through the first air outlet.
